(19) United States
(12) Patent Application Publication
(10) Pub. No.: US 2026/0026324 A1
(43) Pub. Date: Jan. 22, 2026

(54) TUNGSTEN WORDLINE FILL IN HIGH ASPECT RATIO 3D NAND ARCHITECTURE

(71) Applicant: Lam Research Corporation, Fremont, CA (US)

(72) Inventors: Zhongbo YAN, Newark, CA (US); Xiaolan BA, Fremont, CA (US); Erica Maxine CHEN, Newark, CA (US); Yakuan YAO, Campbell, CA (US)

(21) Appl. No.: 18/717,059

(22) PCT Filed: Dec. 12, 2022
(86) PCT No.: PCT/US2022/081398

§ 371 Date: Jun. 6, 2024

Related U.S. Application Data
(60) Provisional application No. 63/265,342, filed on Dec. 13, 2021.

(51) Int. Cl. H01L 21/768; H10B 41/10; H10B 41/27; H10B 41/30; H10B 43/10; H10B 43/27; H10B 43/30

(52) U.S. Cl. CPC H01L 21/76879; H01L 21/76861; H10B 41/10; H10B 41/27; H10B 41/30; H10B 43/10; H10B 43/27; H10B 43/30

(57) ABSTRACT

Feature fill processes including deposition-inhibition-deposition operations use a boron-containing compound treatment to tune an inhibition profile. In some embodiments, a feature is non-conformally treated with a boron-containing compound such as diborane (B₂H₆) prior to an inhibition treatment. Treating the features with a boron-containing chemistry increases the inhibition effect of the subsequently applied inhibition treatment. The diffusion of diborane is easier to control than the diffusion of an inhibition gas such as nitrogen trifluoride (NF₃), facilitating control of the inhibition profile.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Deposition of materials including tungsten-containing materials is an integral part of many semiconductor fabrication processes. These materials may be used for horizontal interconnects, vias between adjacent metal layers, and contacts between metal layers and devices. As devices shrink and more complex patterning schemes are utilized in the industry, deposition of tungsten films becomes a challenge. The continued decrease in feature size and film thickness bring various challenges including high resistivity for thinner films and difficulty in obtaining void-free fill in features. Deposition in complex high aspect ratio structures such as 3D NAND structures is particularly challenging.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Feature fill processes including deposition-inhibition-deposition operations use a boron-containing compound treatment to tune an inhibition profile. In some embodiments, a feature is non-conformally treated with a boron-containing compound such as diborane (B₂H₆) prior to an inhibition treatment. Treating the features with a boron-containing chemistry increases the inhibition effect of the subsequently applied inhibition treatment. The diffusion of diborane is easier to control than the diffusion of an inhibition gas such as nitrogen trifluoride (NF₃), facilitating control of the inhibition profile.

One aspect of the disclosure relates to a method including: providing a 3-D structure of a partially manufactured semiconductor substrate to a chamber, the 3-D structure including sidewalls, a plurality of openings in the sidewalls leading to a plurality of features having a plurality of interior regions fluidically accessible through the openings: depositing a first layer of metal within the 3-D structure such that the first layer lines the plurality of features of the 3-D structure: treating the first layer non-conformally with a boron-containing compound such that that the treatment is preferentially applied at portions of the first layer near the plurality of openings relative to the plurality of interior regions: treating the first layer with a nitrogen species: after treating the first layer with a nitrogen species, depositing a second layer of metal within the 3-D structure on the first layer such that the second layer at least partially fills the plurality of interior regions of the 3-D structure and wherein the second layer of metal is preferentially deposited in the plurality of interior regions relative to the plurality of openings.

In some embodiments, treating the first layer with nitrogen species includes exposing the first layer to nitrogen trifluoride (NF₃). In some embodiments, treating the first layer with nitrogen species includes exposing the first layer to ammonia (NH₃).

In some embodiments, treating the first layer with nitrogen species includes exposing the first layer to a plasma generated from a nitrogen-containing gas. In some embodiments, the boron-containing compound is diborane (B₂H₆).

In some embodiments, the boron-containing compound is introduced to a chamber housing the substrate in the presence of hydrogen (H₂). In some embodiments, the boron-containing compound is introduced to a chamber housing the substrate in the absence of hydrogen (H₂).

Another aspect of the disclosure relates to a method including:
a) providing a 3-D structure of a partially manufactured semiconductor substrate to a chamber, the 3-D structure including sidewalls, a plurality of openings in the sidewalls leading to a plurality of features having a plurality of interior regions fluidically accessible through the openings, wherein the each of the plurality of features includes multiple feature sections separated by pillars;
b) depositing a first layer of metal within the 3-D structure such that the first layer lines the plurality of features of the 3-D structure;
c) treating the first layer non-conformally with a boron-containing compound such that that the treatment is preferentially applied at portions of the first layer near the plurality of openings relative to the plurality of interior regions;
d) treating the first layer with a nitrogen species; and
e) after treating the first layer with the nitrogen species, depositing a second layer of metal within the 3-D structure on the first layer such that the second layer preferentially fills one or more feature sections further within the plurality of features relative to one or more feature sections closer to the nearest sidewall opening.

In some embodiments, the method further includes repeating operations (c), (d), and (e).

In some such embodiments, the second iteration of operation (c) is characterized by one or more of reduced hydrogen flow rate, decreased temperature, reduced boron-containing compound flow rate, or reduced dose time relative to the first iteration of operation (c).

In some such embodiments, the second iteration of operation (d) is characterized by reduced amount of nitrogen species relative to the first iteration of operation (d).

In some embodiments, treating the first layer with nitrogen species includes exposing the first layer to nitrogen trifluoride (NF₃). In some embodiments, treating the first layer with nitrogen species includes exposing the first layer to ammonia (NH₃).

In some embodiments, treating the first layer with nitrogen species includes exposing the first layer to a plasma generated from a nitrogen-containing gas. In some embodiments, the boron-containing compound is diborane (B₂H₆). In some embodiments, the boron-containing compound is introduced to a chamber housing the substrate in the presence of hydrogen (H₂). In some embodiments, the boron-containing compound is introduced to a chamber housing the substrate in the absence of hydrogen (H₂).

These and other features of the disclosure are described further below.

### BRIEF DESCRIPTION OF DRAWINGS

FIGS. 1A-1E present different views and aspects of an example 3-D NAND structure.

FIG. 2 is a schematic representation of a feature at various stages of treatment and fill with tungsten.

FIG. 3 is a schematic representation of a wordline feature at various stages of treatment and fill with tungsten.

FIG. 4 is a process flow diagram illustrating certain operations in methods of filling a feature with tungsten.

FIG. 5 is a process flow diagram illustrating certain operations in methods of filling a 3D NAND wordline feature with tungsten.

FIG. 6 is a schematic representation of a wordline feature at various stages of treatment and fill with tungsten.

FIG. 7 shows a schematic representation of apparatus that may be used to perform the methods described herein.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Provided herein are methods of filling features with metals such as tungsten (W). The methods described herein can be used to fill vertical features, such as in tungsten vias, and horizontal features, such as 3D NAND wordlines. The methods described herein are performed on a substrate that may be housed in a chamber. The substrate may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods are not limit to semiconductor substrates and may be performed to fill any feature with metal.

Substrates may have features such as via or contact holes, which may be characterized by one or more of narrow and/or re-entrant openings, constrictions within the feature, and high aspect ratios. A feature may be formed in one or more of the above described layers. For example, the feature may be formed at least partially in a dielectric layer. In some embodiments, a feature may have an aspect ratio of at least about 2:1, at least about 4:1, at least about 6:1, at least about 10:1, at least about 25:1, or higher. One example of a feature is a hole or via in a semiconductor substrate or a layer on the substrate.

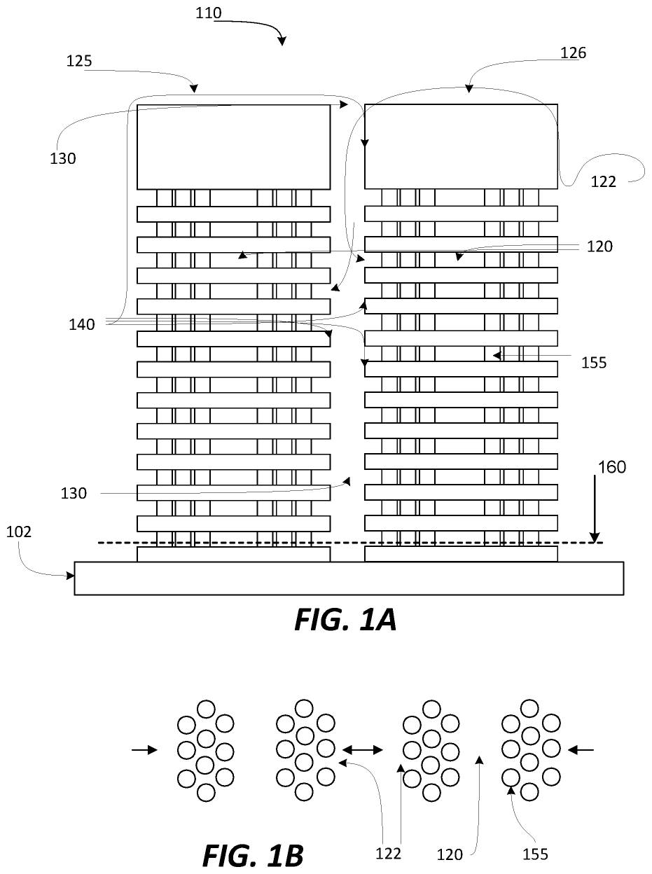

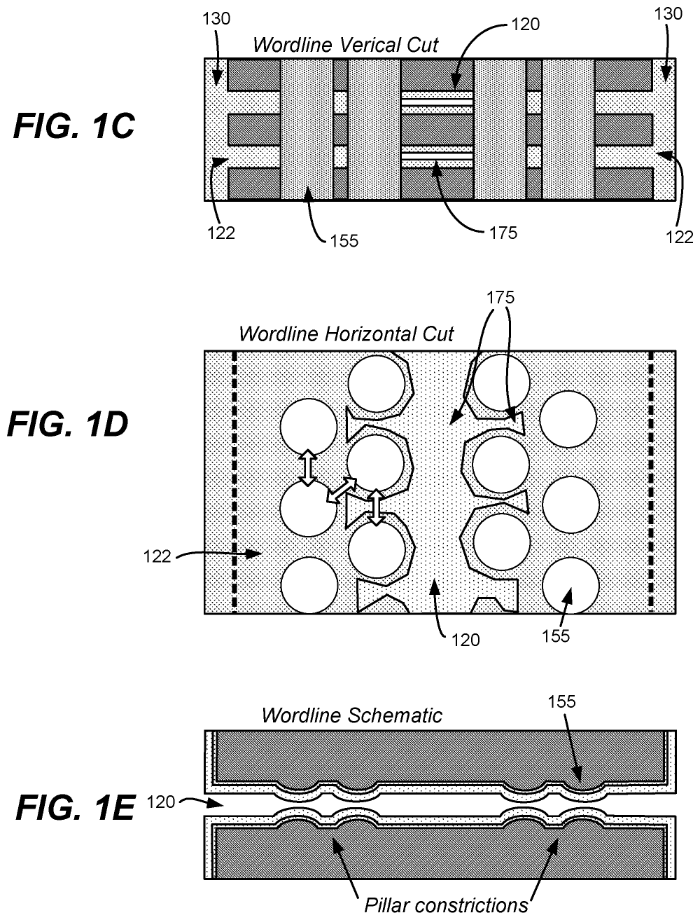

In some embodiments, the methods are used for wordline fill in 3-D NAND structures. FIG. 1A presents a cross-sectional side-view of a 3-D NAND structure 110 (formed on a silicon substrate 102) having VNAND stacks (left 125 and right 126), central vertical structure 130, and a plurality of stacked horizontal features 120 with openings 122 on opposite sidewalls 140 of central vertical structure 130. Note that FIG. 1A displays two stacks of the exhibited 3-D NAND structure 110, which together form the trench-like central vertical structure 130. There may be more than two such stacks arranged in sequence and running spatially parallel to one another with the gap between each adjacent pair of stacks forming a central vertical structure 130, like that illustrated in FIG. 1A. The horizontal features 120 are 3-D memory wordline features that are fluidically accessible from the central vertical structure 130 through the openings 122. The horizontal features 120 present in both the 3-D NAND stacks 125 and 126 shown in FIG. 1A (i.e., the left 3-D NAND stack 125 and the right 3-D NAND stack 126) are also accessible from the other sides of the stacks (far left and far right, respectively) through similar vertical structures formed by additional 3-D NAND stacks (to the far left and far right, but not shown). In other words, each 3-D NAND stack 125, 126 contains a stack of wordline features that are fluidically accessible from both sides of the 3-D NAND stack through a central vertical structure 130. In the particular example schematically illustrated in FIG. 1A, each 3-D NAND stack contains 6 pairs of stacked wordlines, however, in other embodiments, a 3-D NAND memory layout may contain any number of vertically stacked pairs of wordlines.

The wordline features in a 3-D NAND stack may be formed by depositing an alternating stack of silicon oxide and silicon nitride layers, and then selectively removing the nitride layers leaving a stack of oxides layers having gaps between them. These gaps are the wordline features. Any number of wordlines may be vertically stacked in such a 3-D NAND structure so long as there is a technique for forming them available, as well as a technique available to successfully accomplish (substantially) void-free fills of the vertical features. Thus, for example, a 3-D NAND stack may include between 2 and 512 horizontal wordline features, or between 2 and 256 horizontal wordline features, or between 8 and 128 horizontal wordline features, or between 16 and 64 horizontal wordline features, and so forth (the listed ranges understood to include the recited end points).

FIG. 1B presents a cross-sectional top-down view of the same 3-D NAND structure 110 shown in side-view in FIG. 1A with the cross-section taken through the horizontal section 160 as indicated by the dashed horizontal line in FIG. 1A. The cross-section of FIG. 1B illustrates several rows of pillars 155, which run vertically from the base of semiconductor substrate 102 to the top of 3-D NAND stack 110. In some embodiments, these pillars 155 are formed from a polysilicon material. Polysilicon pillars may serve as gate electrodes for stacked memory cells formed within the pillars. The top-view of FIG. 1B illustrates that the pillars 155 form constrictions in the openings 122 to wordline features 120—i.e. fluidic accessibility of wordline features 120 from the central vertical structure 130 via openings 122 (as indicated by the arrows in FIG. 1G) is inhibited by pillars 155. This reduction in fluidic accessibility increases the difficulty of uniformly filling wordline features 120 with material. The structure of wordline features 120 and the challenge of uniformly filling them with material due to the presence of pillars 155 is further illustrated in FIGS. 1C, 1D, and 1E.

FIG. 1C exhibits a vertical cut through a 3-D NAND structure similar to that shown in FIG. 1A, but here focused on a single pair of wordline features 120. FIG. 1C also schematically illustrates a void 175 in the filled wordline features 120. FIG. 1D also schematically illustrates void 175, but in this figure illustrated via a horizontal cut through pillars 155, similar to the horizontal cut exhibited in FIG. 1G. FIG. 1E illustrates the accumulation of tungsten or other metal around the constriction-forming pillars 155, the accumulation resulting in the pinch-off of openings 122, so that no additional metal can be deposited in the region of voids 175. Apparent from Figures IC and ID is that void-free wordline fill relies on migration of sufficient quantities of deposition precursor down through vertical structure 130, through openings 122, past the constricting pillars 155, and into the furthest reaches of wordline features 120, prior to the accumulated deposition of metal around pillars 155 causing a pinch-off of the openings 122 and preventing further precursor migration into wordline features 120. Similarly, FIG. 1E exhibits a single wordline feature 120 viewed cross-sectionally from above and illustrates how a generally conformal deposition of material begins to pinch-off the interior of wordline feature 120 because the significant width of pillars 155 acts to partially block, and/or narrow, and/or constrict what would otherwise be an open path through wordline feature 120. (It should be noted that the example in FIG. 1E can be understood as a 2-D rendering of the 3-D features of the structure of the pillar constrictions shown in FIG. 1D, thus illustrating constrictions that would be seen in a plan view rather than in a cross-sectional view.)

The challenges due to reduced fluidic accessibility increase as 3D NAND structure become more complex. In some embodiments, for example, reactants may diffuse past at least 5, at least 10, at least 15, at least 20, at least 25, or at least 30 pillars to reach the innermost wordline feature. With an increasing number of pillars, the opportunity for pinch-off and internal voids increases.

Examples of feature fill for horizontally-oriented and vertically-oriented features are described below. It should be noted that in at least most cases, the examples are applicable to both horizontally-oriented and vertically-oriented features. Moreover, it should also be noted that in the description below; the term “vertical” may be used to refer to a direction generally orthogonal to the plane of the substrate and the term “lateral” to refer to a direction generally parallel to the plane of the substrate.

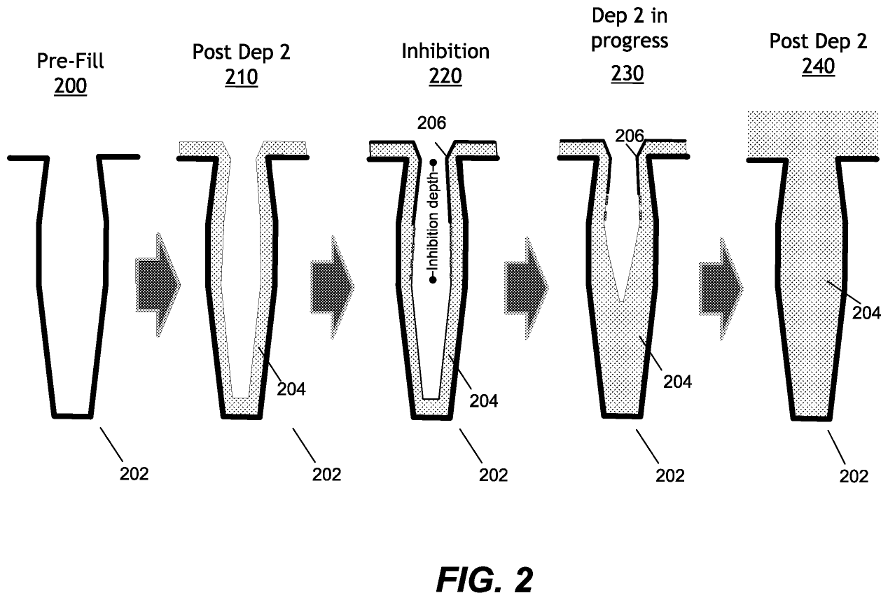

Controlling a deposition profile to reduce or eliminate voids can involve exposure to an inhibition chemistry prior to one or more deposition operations. An example of a feature fill operation including inhibition is illustrated in FIG. 2. In FIG. 2, at 200, an unfilled feature 202 is shown at a pre-fill stage. The feature 202 may be formed in one or more layers on a semiconductor substrate and may optionally have one or more layers that line the sidewalls and/or bottom of the feature. A metal film is deposited in the feature. This operation may be referred to as Dep1 and can be a generally conformal deposition that lines the exposed surfaces of the structures. For example, in a 3D NAND structure such as that shown in FIG. 1A, the metal film lines the wordline features 120. According to various embodiments, the metal film is deposited using an atomic layer deposition (ALD) process to achieve good conformality. Chemical vapor deposition (CVD) processes may be used in alternate embodiments. Still further, the process may also be carried out with any appropriate metal deposition including physical vapor deposition (PVD) or plating processes. The features are not closed off, but sufficiently open to allow further reactant gases to enter the features in a subsequent deposition.

In FIG. 2, at 210, the feature 202 is shown after Dep1 to form a layer of the material 204 to be filled in the feature 202.

Next, deposited metal film is exposed to an inhibition treatment. To promote bottom-up, void-free fill the inhibition treatment may be a non-conformal treatment. A non-conformal treatment is applied preferentially at some parts of feature relative to other. For example, it may be preferentially applied at and near the opening or openings of the feature than in the feature interior. For 3D NAND structures, the treatment may be conformal in the vertical direction such that the bottom wordline feature is treated to approximately the same extent as the top wordline feature, while non-conformal in that the interior of the wordline features are not exposed to the treatment or to a significantly lesser extent than the feature openings.

The inhibition treatment treats the feature surface to inhibit subsequent metal nucleation at the treated surfaces. It can be a thermal treatment, plasma treatment, or be activated by another energy source such as ultraviolet radiation. It can involve one or more of deposition of an inhibition film, reaction of inhibition plasma species or inhibition compound with the Dep1 film to form a compound film (e.g., WN), and adsorption of inhibition species. During the subsequent deposition operation, there is a nucleation delay on the inhibited portions of the underlying film relative to the non- or lesser-inhibited portions (if any). In some embodiments, the inhibition operation includes exposure to a metal precursor, which can be co-flowed with the inhibition gas or delivered in alternating pulses with it.

For inhibition of metals including tungsten, molybdenum, and cobalt, the inhibition treatment can use a nitrogen-containing chemistry. If a plasma is used, it may be a remote or in-situ plasma. In some embodiments, it is generated from nitrogen (N₂) gas, though other nitrogen-containing gases may be used. In some embodiments, the plasma is a radical-based plasma, with no appreciable number of ions. Such plasmas are typically remotely generated. Nitrogen radicals may react with an underlying film to form a metal nitride in some embodiments. For thermal inhibition treatments, a nitrogen- and hydrogen-containing compound such as ammonia (NH₃) or hydrazine (N₂H₄) may be used.

In some embodiments, the inhibition treatment includes both nitrogen and a halogen. For example, a film may be exposed to NF₃ in a thermal inhibition treatment. The NF₃ treatment can both inhibit nucleation and etches deposited metal. Etch removes deposited film at the treated surfaces. This can involve reacting an etchant species with the tungsten or other metal film to form a gaseous byproduct that is then removed. A plasma containing nitrogen species and halogen species may also be used.

In FIG. 2, at 220 the feature 202 is shown after an inhibition treatment. The inhibition treatment is a treatment that has the effect of inhibiting subsequent deposition on the treated surfaces 206. The inhibition may be characterized by an inhibition depth and an inhibition gradient. For non-conformal inhibitions, the inhibition varies with feature depth, e.g., such that the inhibition is greater at the feature opening than at the bottom of the feature and may extend only partway into the feature. In the depicted example of FIG. 2, the inhibition depth is about half of the full feature depth. In addition, the inhibition treatment is stronger at the top of the feature, as graphically shown by the dotted line deeper within the feature.

A second layer of metal is then deposited in the feature. The second deposition may be referred to as Dep2 and may be performed by an ALD or CVD process. For deposition into 3D NAND structures, an ALD process may be used to allow for good step coverage throughout the structure. The Dep2 operation is influenced by the preceding inhibition operation. For example, if the feature openings are preferentially inhibited over the feature interior, deposition will preferentially occur in the feature interior.

In the example of FIG. 2, because deposition is inhibited near the feature opening, during the Dep2 stage shown at 230, the material preferentially deposits at the feature bottom while not depositing or depositing to a lesser extent at the feature opening. This can prevent the formation of voids and seams within the filled feature. As such, during Dep2, the material 204 may be filled in a manner characterized as bottom-up fill rather than the conformal Dep1 fill. As the deposition continues, the inhibition effect may be removed, such that deposition on the lightly treated surfaces may no longer be inhibited. This is illustrated at 230, with the treated surfaces 206 being less extensive than prior to the Dep2 stage. In the example of FIG. 2, as the Dep2 proceeds, the inhibition is eventually overcome on all surfaces and the feature is completely filled with the material 204 as shown at 240.

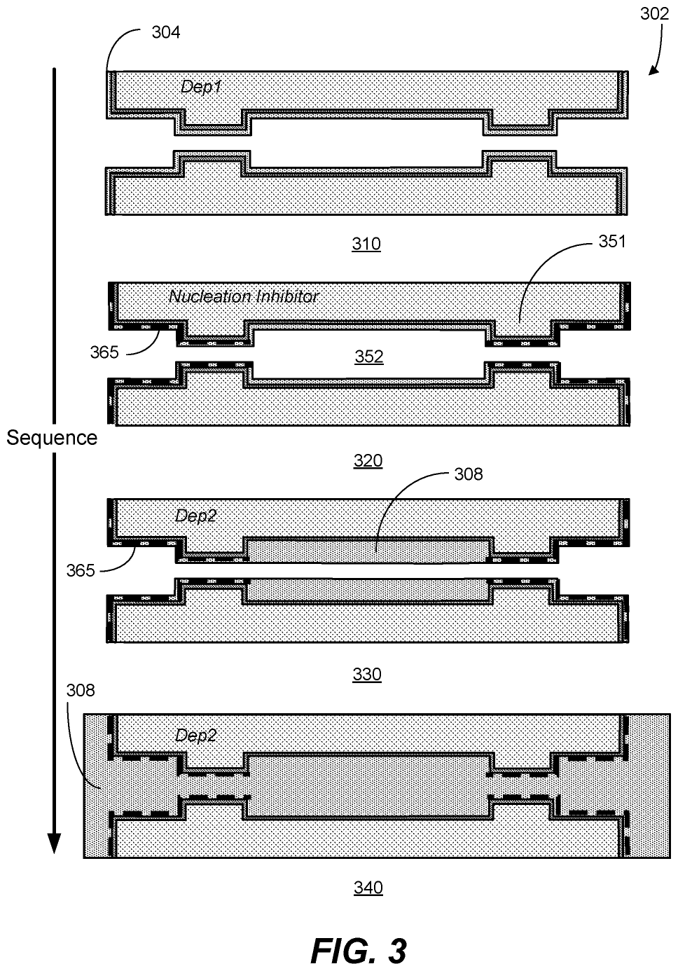

A DID sequence for a wordline in 3D NAND structure is shown in FIG. 3. At 310, the wordline feature 302 is shown after a conformal deposition of a layer of metal 304. At 320, the feature 302 is shown after an inhibition treatment. The treated surfaces 365 extend through the constriction formed by the pillars 351. In this example, the portions 365 through pillar constrictions 351 are inhibited while the surfaces of the interior at 352 are not inhibited. Thus, in the example of FIG. 3, the inhibition treatment is laterally non-conformal. However, the treatment may be uniform in a vertical direction such that each wordline is inhibited at approximately the same areas.

At 330, a process is performed to selectively deposit metal in accordance with the inhibition profile: bulk metal 308 is preferentially deposited on the non-inhibited portions of the metal layer 304, such that hard-to-fill regions behind constrictions are filled. At 340, the bulk deposition continues, filling the remainder of the feature with bulk metal 308.

For 3D NAND deposition, NF₃ can be useful to keep wordlines open by etching deposited metal while inhibiting deposition. An inhibition treatment process using NF₃ can also be advantageous because it allows for a single plenum showerhead. For example, ammonia (NH₃) gas is difficult to purge and may leave residue (after a purge) in the hardware. The residue may react with other process gases such as WF₆, SiH₄, and B₂H₆. Thus, when a gas like NH₃ is used, a dual plenum showerhead that prevents cross contamination of the NH₃ gas residue left in the showerhead and the other process gases may be used. However, NF₃ gas allows a single plenum showerhead to be used. While NF₃ may be reactive with other process gases, a purge operation is able to clear the NF₃ gas and NF₃ residue from the showerhead. This allows use a single plenum showerhead.

One challenge with NF₃ is that it can be difficult to control diffusion. An inhibition profile depends highly on controlling the inhibition gas or species diffusion and on the geometry of the structure. NF₃ diffuses quickly and gets into the inner wordlines quickly. And in complex structures such as 3D NAND wordlines, it can be difficult to purge the NF₃ from the interior of the wordlines. These factors can lead to a stronger inhibition within the wordline than for the outer wordline. The result is deposition in the outer wordline and pinch off of the wordline before complete fill of the inner wordline. This challenge is most prominent in filling the uppermost inner wordlines of a 3D NAND structure.

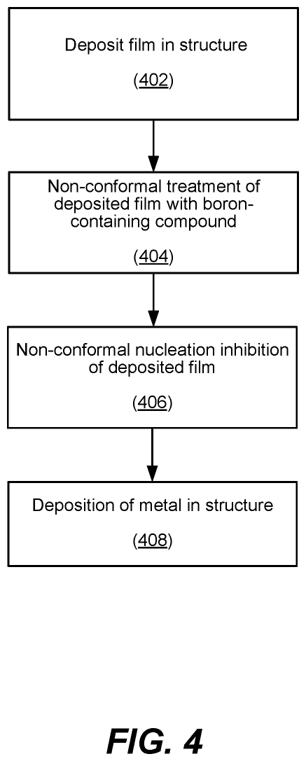

Embodiments described herein include a boron-containing compound to control the inhibition profile. FIG. 4 is a process diagram illustrating operations in filling a structure with metal according to various embodiments. First, a metal film is deposited in the structure in an operation 402. As described above, this operation may be referred to as Dep1. In many embodiments, operation 402 is a generally conformal deposition that lines the exposed surfaces of the structures. For example, in a 3D NAND structure such as that shown in FIG. 1A, the film lines the wordline features 120. According to various embodiments, the metal film is deposited using an ALD process to achieve good conformality. In some embodiments, operation 402 includes ALD deposition of a nucleation layer followed by ALD bulk deposition. Further description of ALD processes are given below. After operation 402, the features are not completely closed off. In some embodiments, the deposition is allowed to proceed until the feature is almost closed off, though still sufficiently open to allow further reactant gases to enter the features in a subsequent deposition.

Next, in an operation 404, the deposited film is non-conformally treated with a boron-containing compound. Non-conformal treatment in this context refers to the treatment being preferentially applied at least at narrow passage or feature opening than in the further in the feature interior. In many embodiments, the boron-containing compound is diborane (B₂H₆). Treating the features with a boron-containing chemistry increases the inhibition effect of the subsequently applied inhibition treatment. This effect may be due to elemental boron forming onto the surface, diborane (or other compound) adsorbing onto the surface, or some combination of these.

Examples of other boron-containing compounds include boranes including BₙHₙ₊₄, BₙHₙ₊₆, BₙHₙ₊₈, BₙHₘ, where n is an integer from 1 to 10, and m is a different integer than m. Other boron-containing compounds may be used, e.g., alkyl boranes, alkyl boron, aminoboranes (CH₃)₂NB(CH₂)₂, carboranes such as C₂BₙHₙ₊₂, and borane halides such as B₂F₄.

The deposited metal film is non-conformally exposed to the boron-containing gas. Diborane is self-decomposing gas. If the amount of diborane is limited (e.g., by one or more of diborane concentration, flow rate, and dose time), the gas will decompose closer to the feature opening without diffusing further into the feature. For 3D NAND structures, the treatment may be conformal in the vertical direction such that the bottom wordline feature is treated to approximately the same extent as the top wordline feature, while non-conformal in that the interior of the wordline features are not exposed to the treatment or to a significantly lesser extent than the narrow passage or feature opening.

In a 3D-NAND structure for example, the diborane will decompose at an outer wordline without diffusing into the innermost wordline. Since the diffusion of diborane is easier to control than the diffusion of NF₃ and diborane increases the inhibition effect of NF₃, it can be used to control the inhibition profile.

Operation 404 can involve a continuous dose or multiple doses of a boron-containing chemistry, separated by purges. Using multiple short doses can facilitate in preventing diffusion further into the feature than desired.

According to various embodiments, diborane may be provided with a nitrogen carrier gas (e.g., 5%/95% B₂H₆/N₂). Argon may be used to further dilute the diborane, e.g., 1:1 Ar:(B₂H₆/N₂) or 2:1 (B₂H₆/N₂).

Substrate temperature during operation 404 may be limited to control the extent of the inhibition. In some embodiments, it is no more than 300° C., or no more than 250° C.

In some embodiments, diborane may be co-flowed with hydrogen (H₂). Hydrogen may be used as parameter to control diborane exposure profile. Diborane decomposes more slowly in the presence of hydrogen than in another carrier gas such as nitrogen (N₂). Thus, for faster decomposition at the outer wordline (or other feature opening), hydrogen may be omitted. For complex structures in which the diborane treatment reaches further into the structure, hydrogen may be added. For example, in some 3D NAND structures with multiple pillars, hydrogen may be added to allow the diborane to pass one or more pillars before decomposing or otherwise treating the film.

After the non-conformal treatment with a boron-containing compound, nucleation on the deposited film is non-conformally inhibited in an operation 406. As with operation 404, non-conformal treatment in this context refers to the treatment being preferentially applied at least at narrow passage or feature opening than in the further in the feature interior. For 3D NAND structures, the treatment may be conformal in the vertical direction such that the bottom wordline feature is treated to approximately the same extent as the top wordline feature, while non-conformal in that the interior of the wordline features are not exposed to the treatment or to a significantly lesser extent than the narrow passage or feature opening.

Nucleation inhibition inhibits subsequent metal nucleation at the treated surfaces. It can involve one or more of: deposition of an inhibition film, reaction of treatment species with the metal film to form a compound film, and adsorption of inhibition species. During the subsequent deposition operation, there is a nucleation delay on the inhibited portions of the underlying film relative to the non- or lesser-inhibited portions.

In some embodiments, NF₃ is used in a thermal inhibition process. Other nitrogen-containing gases such as ammonia (NH₃) or hydrazine (N₂H₄) may be used for thermal inhibition processes. The inhibition may also be a plasma inhibition, with a nitrogen-containing gas such as N₂ used to generate a plasma in a remote or in-situ chamber.

To tailor lateral non-conformality in the wordlines, pressure and treatment gas flow rate may be adjusted. Higher chamber pressure and lower treatment gas flow rate (and/or concentration) promotes treatment at the openings of the wordline features over treatment within the interiors of the wordline features. Thus, in some embodiments, chamber pressure may lower from operation 402 to 406. Example chamber pressures range from 3 Torr to 40 Torr. And, because the diborane increases the inhibition effect, non-conformality of the inhibition can be controlled by the operation 404 as well as the parameters of operation 406.

In some embodiments, a treatment gas is pressurized to level significantly higher than the chamber pressure prior to introduction to chamber. This facilitates the gas reaching the bottommost portion of the vertical structure. In the example of NF₃ gas, the NF₃ gas may be pressurized in a charge volume to a pressure between 10 Torr and 1000 Torr. In some embodiments, the pressure is between 400 Torr and 500 Torr.

Operation 406 may be a continuous flow or pulsed process. In the latter case, different gases may be pulsed in sequence to tune the treatment.

After operation 406, a second deposition is performed in operation 408. The second deposition may be performed by an ALD or CVD process. For deposition into 3D NAND structures, an ALD process may be used to allow for good step coverage throughout the structure. Gases more easily reach feature interiors due to the effects of the treatment. After an etch process, film deposited near the feature entrance is removed, allowing more space for gases to reach the interior of the feature and preventing pinch-off. In some embodiments, enough metal film may be removed such that an underlying surface is wholly or partially exposed, increasing nucleation delay at these areas. After an inhibition process, nucleation delay is increased, allowing an inside-out fill process. Operation 408, which may be referred to as a Dep2 process, may complete fill of the structures in some embodiments. In other embodiments, one more additional treatment/deposition operations may be performed.

According to various embodiments, each of operations 402, 404, 406, and 408 may be performed in the same processing chamber or in different processing chambers. If performed in the same chamber, they may be performed in a single-station or multi-station chamber. In a multi-station chamber, various operations may be performed at various stations. For example, operation 402 may be performed in a first station, operation 404 in a second station, operation 406 in a third station, and operation 408 in a fourth station. In some embodiments, while various operations are performed in separate stations within a single chamber, only a single operation, i.e., operation 402, depositing metal film in a structure, may be performed at a time. In another embodiment, when multiple substrates are being processed, various operations may occur concurrently. For example, a first substrate is at station one for operation 402 and a second substrate is at station two for operation 406 in the same multi-station chamber. Both operation 404 and operation 406 may proceed concurrently in the same multi-station chamber. In some embodiments, chamber pressure may be low to prevent any cross-contamination or safety issues. In one example, in operation 404, a structure may be treated using a boron-containing compound (e.g., B₂H₆) in station one on a first substrate. A second substrate may be undergoing operation 404 using NF₃ in a second station. Both the B₂H₆ treatment in station one and the NF₃ in station two can occur concurrently in the same multi-station chamber. To achieve this, the chamber pressure is set to a lower pressure, such as a pressure below 25 Torr.

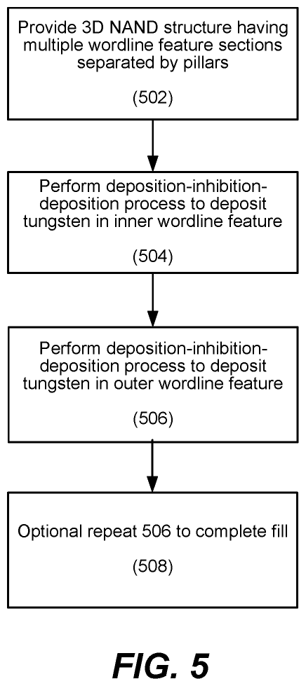

FIG. 5 is a process diagram illustrating operations in filling a 3D NAND structure with tungsten according to various embodiments. First, in an operation 502, a 3D NAND structure having multiple wordline feature sections separated by pillars is provided. Then, in an operation 504, a deposition-inhibition-deposition (DID) process as described above is performed to deposit tungsten in an inner wordline feature. This may fill the innermost wordline, while leaving outer wordlines at least partially unfilled. The inhibition operation of the DID process of operation 504 may be performed as described above with respect to FIG. 4, and include non-conformal treatment using a boron-containing compound. Next, an inhibition-deposition process is performed in an operation 506 to deposit tungsten in an outer wordline. According to various embodiments, treatment with a boron-containing compound and/or an inhibition operation of operation 506 may differ from that of operation 504. This is because the inhibition does not extend as deeply into the interior of the structure. Operation 506 may be optionally repeated in an operation 508 to complete the fill.

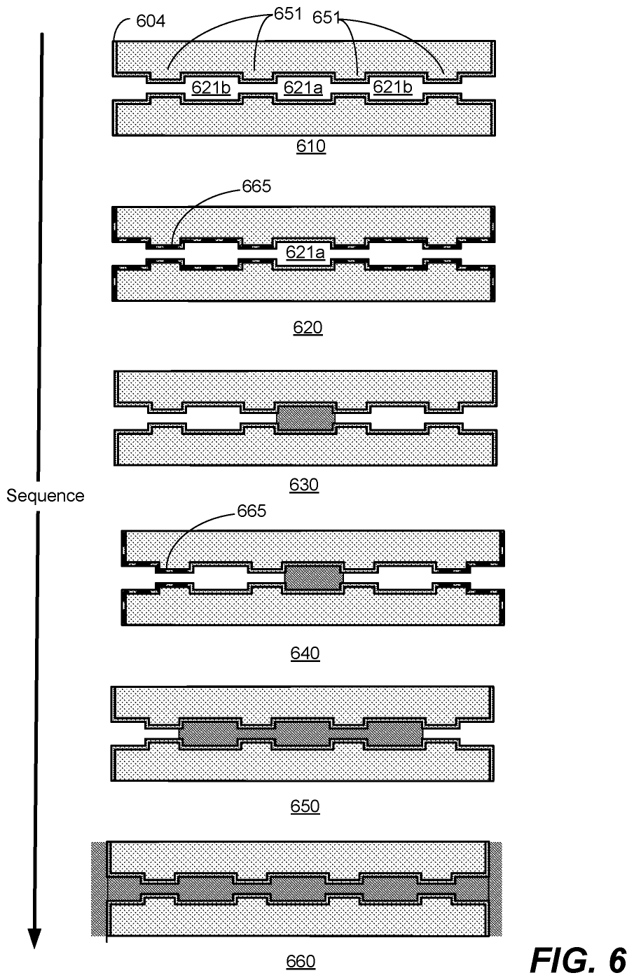

An example of a deposition-inhibition-deposition-inhibition-deposition (DIDID) sequence as described in FIG. 5 is shown in FIG. 6. At 610, a wordline feature including an inner wordline feature 621a is shown after a first deposition. Wordline feature section 621a is separated from wordline feature sections 621b by pillars 651. A conformal film 604 of tungsten lines the structure. At 620, portions 665 of the conformal film are inhibited. The inhibition is controlled to inhibit through the constrictions created by pillars 651 that separate the inner wordline feature 621a from the adjacent wordline sections 621b. At 630, tungsten fill after a subsequent deposition is shown. Tungsten deposits in the innermost wordline feature 621a. At 640, a subsequent inhibition is shown. The inhibited portions 665 are shallower than those at 620. If the same inhibition process were to be used, the inhibition may be too deep. In some embodiments, treatment using the boron-containing compound is modified. For example, hydrogen flow may be reduced or removed, the temperature may be decreased, boron-containing compound flow rate may be decreased, and/or boron-containing compound dose time may be decreased. At 650 and 660, subsequent deposition is shown with outer wordlines filled. This may be process may be repeated as needed to fill the structure. Structures of arbitrary size and complexity may be filled by repeated inhibition-deposition operations.

In the examples above, deposition of a conformal layer (e.g., in operation 402 of FIG. 4) can involve deposition of a nucleation layer. While the nucleation layer can serve as the initial conformal layer in some embodiments, a conformal bulk layer may be deposited on the nucleation layer to form the conformal of the initial deposition.

A nucleation layer is a layer that facilitates subsequent deposition of bulk metal-containing material thereon. It is typically thin and conformal. According to various implementations, a metal nucleation layer may be deposited prior to any fill of the feature and/or at subsequent points during fill of the feature.

In certain implementations, the nucleation layer is deposited using a cyclical process of sequentially adding reactants for reaction in the feature. The may be an atomic layer deposition (ALD) process and/or a pulsed nucleation layer (PNL) technique. In such a technique, pulses of a reducing agent, optional purge gases, and metal-containing precursor are sequentially injected into and purged from the reaction chamber. The process is repeated in a cyclical fashion until the desired thickness is achieved. PNL techniques for depositing tungsten nucleation layers are described in U.S. Pat. Nos. 6,635,965; 7,005,372; 7,141,494; 7,589,017, 7,772,114, 7,955,972 and 8,058,170, and U.S. Patent Publication No. 2010-0267235, all of which are incorporated by reference herein in their entireties.

Nucleation layer thickness can depend on the nucleation layer deposition method as well as the desired quality of bulk deposition. In general, nucleation layer thickness is sufficient to support high quality, uniform bulk deposition. Examples may range from 5 Å-100 Å, e.g., 5 Å to 30 Å.

In certain implementations, a bulk layer may be deposited directly in a feature without use of a nucleation layer. For example, in some implementations, the feature surface and/or an already-deposited under-layer supports bulk deposition.

Tungsten nucleation layer deposition can involve exposure to alternating pulses of a tungsten-containing precursor (also referred to as a tungsten precursor) and a reducing agent, separated by an inert purge gas. For tungsten deposition, examples of precursors include tungsten hexafluoride (WF₆). Chlorine-containing tungsten precursors (WClₓ) such as tungsten pentachloride (WCl₅) and tungsten hexachloride (WCl₆) may be used. These precursors may be reduced to elemental tungsten (W) by reaction with reducing agents such as silane (SiH₄) and diborane (B₂H₆).

In alternate embodiments, a metal precursor and a reducing agent may be co-flowed. If co-flowed, a sequence in which the metal precursor and reducing agent are co-flowed in pulses may be used. During the reactant doses, the metal precursor and reducing agent are co-flowed into the chamber. Co-flowing the reactants is more similar to a CVD reaction, which results in a higher deposition rate and rougher nucleation layer. Various modifications may be made to the sequence. For example, the metal precursor and reducing agent reactant pulses may be offset but overlap with a delay for one reactant with respect to the other. In another example, the inert gas may be pulsed for the purge phase.

Examples of reducing agents can include boron-containing reducing agents including B₂H₆ and other boranes, silicon-containing reducing agents including SiH₄ and other silanes, hydrazine, and germanes. In some implementations, pulses of tungsten-containing precursors can be alternated with pulses of one or more reducing agents, e.g., S/W/S/W/B/W, etc., where W represents a tungsten-containing precursor, S represents a silicon-containing precursor, and B represents a boron-containing precursor. In some implementations, a separate reducing agent may not be used, e.g., an organometallic tungsten-containing precursor may undergo thermal or plasma-assisted decomposition.

According to various implementations, hydrogen may or may not be run in the background. Further, in some implementations, deposition of a tungsten nucleation layer may be followed by one or more treatment operations prior to tungsten bulk deposition. Treating a deposited tungsten nucleation layer to lower resistivity is described for example in U.S. Pat. Nos. 7,772,114 and 8,058,170 and U.S. Patent Publication No. 2010-0267235, incorporated by reference herein.

Bulk deposition can occur by an ALD or CVD process. In a CVD process, a reducing agent and a metal precursor are co-flowed into a deposition chamber to deposit a bulk fill layer in the feature. An inert carrier gas may be used to deliver one or more of the reactant streams, which may or may not be pre-mixed. This operation generally involves flowing the reactants continuously until the desired amount is deposited. In certain implementations, the CVD operation may take place in multiple stages, with multiple periods of continuous and simultaneous flow of reactants separated by periods of one or more reactant flows diverted.

For conformal deposition and deposition into complex structures such as 3D NAND structures, ALD deposition of a bulk layer may be used. ALD deposition of a bulk layer involves exposure to alternating pulses of a metal-containing precursor and a reducing agent, separated by an inert purge gas, using the metal precursors described above with reference to nucleation layer deposition. The same or different metal precursor used in nucleation layer deposition may be used for bulk deposition. In contrast to nucleation layer deposition in which a strong reducing agent such as diborane or silane may be used, hydrogen is often the reducing agent for bulk deposition.

Deposition may proceed according to various implementations until a certain feature profile is achieved and/or a certain amount of metal is deposited. In some implementations, the deposition time and other relevant parameters may be determined by modeling and/or trial and error. In some implementations, a process chamber may be equipped with various sensors to perform in-situ metrology measurements for end-point detection of a deposition operation.

Examples of in-situ metrology include optical microscopy and X-Ray Fluorescence (XRF) for determining thickness of deposited films.

In some embodiments, the conformal tungsten layer may be characterized as low resistivity and, in some embodiments, low stress and/or low fluorine. Because the wordline features are unfilled (with the exception of the nucleation layer if deposited), a relatively fast deposition technique may be used. In some embodiments, this involves alternating pulses of a W-containing precursor, such as tungsten hexafluoride (WF₆), and hydrogen (H₂) or other reducing agent to deposit the first tungsten layer in an ALD process. Purge operations may separate the pulses. Relatively short pulse times may be used for deposition to increase throughput.

The second or subsequent bulk layer deposited (e.g., a Dep2 operation or operation 408 in FIG. 4) may be deposited using a second set of conditions than the first layer bulk layer. Like the first bulk layer, the second bulk layer may be a low resistivity layer, and in some embodiments, a low stress and/or low fluorine layer. In some embodiments, a bulk layer deposition after the initial bulk layer deposition may involve increased pulse times and increased purge times relative to the initial bulk layer deposition. In particular embodiments, metal-containing precursor pulse times may be increased. Increasing pulse and/or purge times can facilitate reactants diffusing into the wordlines. In some embodiments, the temperature may also be changed from operation 402 to operation 408: for example, higher temperature may be used to speed reaction time. In some embodiments, a lower temperature may be used to allow the reactants to diffuse into the wordline features before reaction. In some embodiments, the second set of conditions may include a change in flowrates. For example, the flow rate of the metal-containing precursor and/or reducing agent may be increased.

In some embodiments, as an overburden layer may be deposited at different conditions. This layer may be characterized that is removed in a subsequent step and can be deposited on sidewalls such as sidewalls 140 in the 3D NAND structure of FIG. 1A. Examples of overburden layers are shown at 340 in FIGS. 3 and 660 in FIG. 6. In some embodiments, an overburden layer may have low roughness. Higher resistivity and/or fluorine concentration can be tolerated as the tungsten is to be removed. Deposition of an overburden layer can involve any one of: faster timing if ALD is used with shorter pulse times than during deposition of the second or other intermediate bulk W layer, using CVD instead of ALD, and introducing nitrogen (N₂) during or between the flow of one or more reactant gases.

The methods described above with reference to FIGS. 5 and 6 may be used to fill a feature with another metal by using the appropriate metal-containing precursor as described below.

### Metal-Containing Precursors

While WF₆ is used as an example of a tungsten-containing precursor in the above description, other tungsten-containing precursors may be suitable for performing disclosed embodiments. For example, a metal-organic tungsten-containing precursor may be used. Organo-metallic precursors and precursors that are free of fluorine, such as MDNOW (methylcyclopentadienyl-dicarbonylnitrosyl-tungsten) and EDNOW (ethylcyclopentadienyl-dicarbonylnitrosyl-tungsten) may also be used. Chlorine-containing tungsten precursors (WClₓ) such as tungsten pentachloride (WCl₅) and tungsten hexachloride (WCl₆) may be used.

To deposit molybdenum (Mo), Mo-containing precursors including molybdenum hexafluoride (MoF₆), molybdenum pentachloride (MoCl₅), molybdenum dichloride dioxide (MoO₂Cl₂), molybdenum tetrachloride oxide (MoOCl₄), and molybdenum hexacarbonyl (Mo(CO)₆) may be used.

To deposit ruthenium (Ru), Ru-precursors may be used. Examples of ruthenium precursors that may be used for oxidative reactions include (ethylbenzyl) (1-ethyl-1,4-cyclohexadienyl) Ru(0), (1-isopropyl-4-methylbenzyl) (1,3-cyclohexadienyl) Ru(0), 2,3-dimethyl-1,3-butadienyl) Ru(0)tricarbonyl, (1,3-cyclohexadienyl) Ru(0)tricarbonyl, and (cyclopentadienyl) (ethyl) Ru(II) dicarbonyl. Examples of ruthenium precursors that react with non-oxidizing reactants are bis(5-methyl-2,4-hexanediketonato) Ru(II) dicarbonyl and bis(ethylcyclopentadienyl) Ru(II).

To deposit cobalt (Co), cobalt-containing precursors including dicarbonyl cyclopentadienyl cobalt (I), cobalt carbonyl, various cobalt amidinate precursors, cobalt diazadienyl complexes, cobalt amidinate/guanidinate precursors, and combinations thereof may be used.

The metal-containing precursor may be reacted with a reducing agent as described above. In some embodiments, H₂ is used as a reducing agent for bulk layer deposition to deposit high purity films.

### Nucleation Layer Deposition

In some implementations, the methods described herein involve deposition of a nucleation layer prior to deposition of a bulk layer. For example, deposition of a conformal layer in a Dep1 operation may involve deposition of a nucleation layer followed by ALD of a thin bulk layer.

A nucleation layer is typically a thin conformal layer that facilitates subsequent deposition of bulk material thereon. For example, a nucleation layer may be deposited prior to any fill of the feature and/or at subsequent points during fill of the feature (e.g., via interconnect) on a wafer surface. For example, in some implementations, a nucleation layer may be deposited following etch of tungsten in a feature, as well as prior to initial tungsten deposition.

In certain implementations, the nucleation layer is deposited using a pulsed nucleation layer (PNL) technique. In a PNL technique to deposit a tungsten nucleation layer, pulses of a reducing agent, optional purge gases, and tungsten-containing precursor are sequentially injected into and purged from the reaction chamber. The process is repeated in a cyclical fashion until the desired thickness is achieved. PNL broadly embodies any cyclical process of sequentially adding reactants for reaction on a semiconductor substrate, including atomic layer deposition (ALD) techniques. Nucleation layer thickness can depend on the nucleation layer deposition method as well as the desired quality of bulk deposition. In general, nucleation layer thickness is sufficient to support high quality, uniform bulk deposition. Examples may range from 10 Å-100 Å.

The methods described herein are not limited to a particular method of nucleation layer deposition but include deposition of bulk film on nucleation layers formed by any method including PNL, ALD, CVD, and physical vapor deposition (PVD). Moreover, in certain implementations, bulk tungsten may be deposited directly in a feature without use of a nucleation layer. For example, in some implementations, the feature surface and/or an already-deposited under-layer supports bulk deposition. In some implementations, a bulk deposition process that does not use a nucleation layer may be performed.

In various implementations, nucleation layer deposition can involve exposure to a metal precursor as described above and a reducing agent. Examples of reducing agents can include boron-containing reducing agents including diborane (B₂H₆) and other boranes, silicon-containing reducing agents including silane (SiH₄) and other silanes, hydrazines, and germanes. In some implementations, pulses of metal-containing can be alternated with pulses of one or more reducing agents, e.g., S/W/S/W/B/W, etc., W representing a tungsten-containing precursor, S represents a silicon-containing precursor, and B represents a boron-containing precursor. In some implementations, a separate reducing agent may not be used, e.g., a tungsten-containing precursor may undergo thermal or plasma-assisted decomposition.

### Bulk Deposition

As described above, bulk deposition may be performed across a wafer. In some implementations, bulk deposition can occur by a CVD process in which a reducing agent and a metal-containing precursor are flowed into a deposition chamber to deposit a bulk fill layer in the feature. An inert carrier gas may be used to deliver one or more of the reactant streams, which may or may not be pre-mixed. Unlike PNL or ALD processes, this operation generally involves flowing the reactants continuously until the desired amount is deposited. In certain implementations, the CVD operation may take place in multiple stages, with multiple periods of continuous and simultaneous flow of reactants separated by periods of one or more reactant flows diverted. Bulk deposition may also be performed using ALD processes in which a metal-containing precursor is alternated with a reducing agent such as H₂. In some implementations, ALD may be used to deposit an initial bulk layer in a Dep1 process with CVD used for the remaining feature fill after inhibition. In some implementations, ALD may be used for feature fill with CVD used for an overburden layer. In some implementations, ALD may be used for all of the bulk layer deposition.

It should be understood that the metal films described herein may include some amount of other compounds, dopants and/or impurities such as nitrogen, carbon, oxygen, boron, phosphorous, sulfur, silicon, germanium and the like, depending on the particular precursors and processes used. The metal content in the film may range from 20% to 100% (atomic) metal. In many implementations, the films are metal-rich, having at least 50% (atomic) metal, or even at least about 60%, 75%, 90%, or 99% (atomic) metal. In some implementations, the films may be a mixture of metallic or elemental metal (e.g., W, Mo, Co, or Ru) and other metal-containing compounds such as tungsten carbide (WC), tungsten nitride (WN), molybdenum nitride (MoN) etc. CVD and ALD deposition of these materials can include using any appropriate precursors as described above.

### Inhibition of Metal Nucleation

Plasma inhibition processes involve exposure to a plasma generated from a nitrogen containing compound, such as N₂. Plasma power, chamber pressure, and/or process gases may be pulsed in some embodiments.

Thermal inhibition processes generally involve exposing the feature to a nitrogen-containing compound such as ammonia (NH₃) or hydrazine (N₂H₄) to non-conformally inhibit the feature near the feature opening. In some embodiments, the thermal inhibition processes are performed at temperatures ranging from 250° C., to 450° C. At these temperatures, exposure of a previously formed tungsten or other layer to NH₃ results in an inhibition effect. Other potentially inhibiting chemistries such as nitrogen (N₂) or hydrogen (H₂) may be used for thermal inhibition at higher temperatures (e.g., 900° C.). For many applications, however, these high temperatures exceed the thermal budget. In addition to ammonia, other hydrogen-containing nitriding agents such as hydrazine may be used at lower temperatures appropriate for back end of line (BEOL) applications. During thermal inhibition, a metal precursor may be flowed with the inhibition gas or in alternating pulses with the gas.

Nitridation of a surface can passivate it. Subsequent deposition of tungsten or other metal such as molybdenum or cobalt on a nitrided surface is significantly delayed, compared to on a regular bulk tungsten film. In addition to NF₃, fluorocarbons such as CF₄ or C₂F₈ may be used. However, in certain implementations, the inhibition species are fluorine-free to prevent etching during inhibition.

In addition to the surfaces described above, nucleation may be inhibited on liner/barrier layers surfaces such as TiN and/or WN surfaces. Any chemistry that passivates these surfaces may be used. Inhibition chemistry can also be used to tune an inhibition profile, with different ratios of active inhibiting species used. For example, for inhibition of W surfaces, nitrogen may have a stronger inhibiting effect than hydrogen: adjusting the ratio of N₂ and H₂ gas in a forming gas can be used to tune a profile.

In certain implementations, the substrate can be heated up or cooled down before inhibition. A predetermined temperature for the substrate can be selected to induce a chemical reaction between the feature surface and inhibition species and/or promote adsorption of the inhibition species, as well as to control the rate of the reaction or adsorption. For example, a temperature may be selected to have high reaction rate such that more inhibition occurs near the gas source.

After inhibition, the inhibition effect may be modulated as described above. In the same or other embodiments, it may also be modulated by soaking it in a reducing agent or metal precursor, exposing it to a hydrogen-(H-)containing plasma, performing a thermal anneal, exposing it an air, which can reduce the inhibition effect.

### Apparatus

Any suitable chamber may be used to implement the disclosed embodiments. Example deposition apparatuses include various systems, e.g., ALTUS® and ALTUS® Max, available from Lam Research Corp., of Fremont, California, or any of a variety of other commercially available processing systems.

In some embodiments, a first deposition may be performed at a first station that is one of two, five, or even more deposition stations positioned within a single deposition chamber. Thus, for example, hydrogen (H₂) and tungsten hexafluoride (WF₆) may be introduced in alternating pulses to the surface of the semiconductor substrate, at the first station, using an individual gas supply system that creates a localized atmosphere at the substrate surface. The same or another station may be used for boron treatment. Another station may be used for NF₃ treatment, and a fourth for subsequent ALD bulk fill.

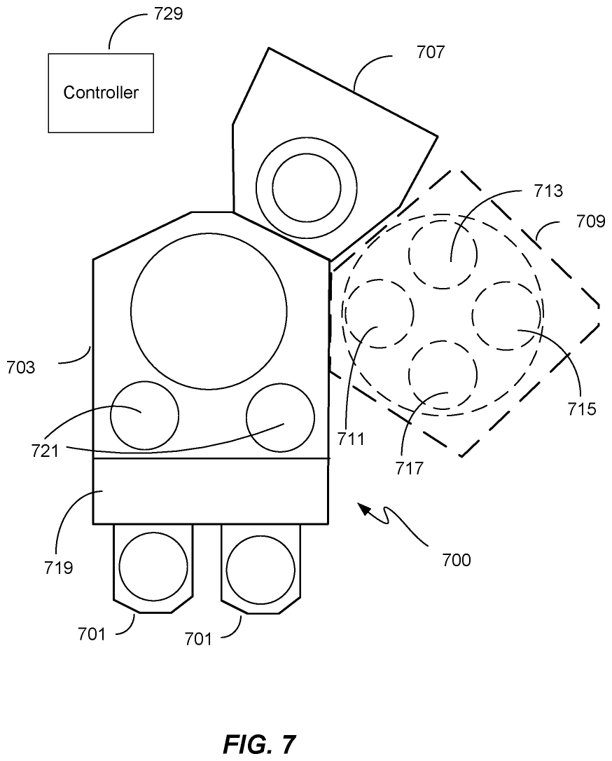

FIG. 7 is a schematic of a process system suitable for conducting deposition processes in accordance with embodiments. The system 700 includes a transfer module 703. The transfer module 703 provides a clean, pressurized environment to minimize risk of contamination of substrates being processed as they are moved between various reactor modules. Mounted on the transfer module 703 is a multi-station reactor 709 capable of performing ALD, treatment, and CVD according to various embodiments. Multi-station reactor 709 may include multiple stations 711, 713, 715, and 717 that may sequentially perform operations in accordance with disclosed embodiments. For example, multi-station reactor 709 may be configured such that station 711 performs a tungsten nucleation layer deposition using a tungsten precursor and a boron- or silicon-containing reducing agent and ALD tungsten bulk deposition of a conformal layer using H₂ as reducing agent, station 713 performs treatment using a boron-containing compound, station 715 performs a NF₃ treatment operation, and station 717 may perform a bulk ALD fill after treatment using H₂ ae reducing agent.

Stations may include a heated pedestal or substrate support, one or more gas inlets or showerhead or dispersion plate.

Returning to FIG. 7, also mounted on the transfer module 703 may be one or more single or multi-station modules 707 capable of performing plasma or chemical (non-plasma) pre-cleans, other deposition operations, or etch operations. The module may also be used for various treatments to, for example, prepare a substrate for a deposition process. The system 700 also includes one or more wafer source modules 700, where wafers are stored before and after processing. An atmospheric robot (not shown) in the atmospheric transfer chamber 719 may first remove wafers from the source modules 701 to loadlocks 721. A wafer transfer device (generally a robot arm unit) in the transfer module 703 moves the wafers from loadlocks 721 to and among the modules mounted on the transfer module 703.

In various embodiments, a system controller 729 is employed to control process conditions during deposition. The controller 729 will typically include one or more memory devices and one or more processors. A processor may include a CPU or computer, analog and/or digital input/output connections, stepper motor controller boards, etc.

The controller 729 may control all of the activities of the deposition apparatus. The system controller 729 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 729 may be employed in some embodiments.

Typically, there will be a user interface associated with the controller 729. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general-purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 729. The signals for controlling the process are output on the analog and digital output connections of the deposition apparatus 700.

The system software may be designed or configured in many different ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller 729 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems 30) may be integrated with electronics for controlling their operation before, during, and after processing of a semiconductor wafer or substrate. The electronics may be referred to as the “controller,” which may control various components or subparts of the system or systems. The controller 729, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems. RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 729, in some implementations, may be a part of or coupled to a computer that is integrated with, coupled to the system, otherwise networked to the system, or a combination thereof. For example, the controller 729 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. The parameters may be specific to the type of process to be performed and the type of tool that the controller is configured to interface with or control. As described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 729 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating. e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool: (2) curing of photoresist using a hot plate or furnace or UV curing tool: (3) exposing the photoresist to visible or UV or x-ray light with a tool such as a wafer stepper: (4) developing the resist so as to selectively remove resist and thereby pattern it using a tool such as a wet bench: (5) transferring the resist pattern into an underlying film or workpiece by using a dry or plasma-assisted etching tool; and (6) removing the resist using a tool such as an RF or microwave plasma resist stripper.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method comprising:
providing a 3-D structure of a partially manufactured semiconductor substrate to a chamber, the 3-D structure comprising sidewalls, a plurality of openings in the sidewalls leading to a plurality of features having a plurality of interior regions fluidically accessible through the openings;
depositing a first layer of metal within the 3-D structure such that the first layer lines the plurality of features of the 3-D structure;
treating the first layer non-conformally with a boron-containing compound such that that the treatment is preferentially applied at portions of the first layer near the plurality of openings relative to the plurality of interior regions;
treating the first layer with a nitrogen species;
after treating the first layer with a nitrogen species, depositing a second layer of metal within the 3-D structure on the first layer such that the second layer at least partially fills the plurality of interior regions of the 3-D structure and wherein the second layer of metal is preferentially deposited in the plurality of interior regions relative to the plurality of openings.

2. The method of claim 1, wherein treating the first layer with nitrogen species comprises exposing the first layer to nitrogen trifluoride (NF₃).

3. The method of claim 1, wherein the treating first layer with nitrogen species comprises exposing the first layer to ammonia (NH₃).

4. The method of claim 1, wherein treating the first layer with nitrogen species comprises exposing the first layer to a plasma generated from a nitrogen-containing gas.

5. The method of claim 1, wherein the boron-containing compound is diborane (B₂H₆).

6. The method of claim 1, wherein the boron-containing compound is introduced to a chamber housing the substrate in the presence of hydrogen (H₂).

7. The method of claim 1, wherein the boron-containing compound is introduced to a chamber housing the substrate in the absence of hydrogen (H₂).

8. A method comprising:
a) providing a 3-D structure of a partially manufactured semiconductor substrate to a chamber, the 3-D structure comprising sidewalls, a plurality of openings in the sidewalls leading to a plurality of features having a plurality of interior regions fluidically accessible through the openings, wherein the each of the plurality of features includes multiple feature sections separated by pillars;
b) depositing a first layer of metal within the 3-D structure such that the first layer lines the plurality of features of the 3-D structure;
c) treating the first layer non-conformally with a boron-containing compound such that that the treatment is preferentially applied at portions of the first layer near the plurality of openings relative to the plurality of interior regions;
d) treating the first layer with a nitrogen species; and
e) after treating the first layer with the nitrogen species, depositing a second layer of metal within the 3-D structure on the first layer such that the second layer preferentially fills one or more feature sections further within the plurality of features relative to one or more feature sections closer to the nearest sidewall opening.

9. The method of claim 8, further comprising repeating operations (c), (d), and (e).

10. The method of claim 9, wherein the second iteration of operation (c) is characterized by one or more of reduced hydrogen flow rate, decreased temperature, reduced boron-containing compound flow rate, or reduced dose time relative to the first iteration of operation (c).

11. The method of claim 10, wherein the second iteration of operation (d) is characterized by reduced amount of nitrogen species relative to the first iteration of operation (d).

12. The method of claim 8, wherein treating the first layer with nitrogen species comprises exposing the first layer to nitrogen trifluoride (NF₃).

13. The method of claim 8, wherein treating the first layer with nitrogen species comprises exposing the first layer to ammonia (NH₃).

14. The method of claim 8, wherein treating the first layer with nitrogen species comprises exposing the first layer to a plasma generated from a nitrogen-containing gas.

15. The method of claim 8, wherein boron-containing compound is diborane (B₂H₆).

16. The method of claim 8, wherein the boron-containing compound is introduced to a chamber housing the substrate in the presence of hydrogen (H₂).

17. The method of claim 8, wherein the boron-containing compound is introduced to a chamber housing the substrate in the absence of hydrogen (H₂).
